(19) United States
(12) Patent Application Publication
(10) Pub. No.: US 2025/0089280 A1
(43) Pub. Date: Mar. 13, 2025

(54) SEMICONDUCTOR DEVICE INCLUDING CAPACITOR STRUCTURE

(71) Applicant: SAMSUNG ELECTRONICS CO., LTD., Suwon-si (KR)

(72) Inventors: Ingyu Baek, Suwon-si (KR); Kumhyo Kang, Suwon-si (KR); Hyunmook Choi, Suwon-si (KR); Soonhyung Hong, Suwon-si (KR)

(21) Appl. No.: 18/809,515

(22) Filed: Aug. 20, 2024

(30) Foreign Application Priority Data
Sep. 12, 2023 (KR) 10-2023-0121274

(51) Int. Cl. H01G 4/30

(52) U.S. Cl. CPC H10D 1/714

(57) ABSTRACT

An example semiconductor device includes a capacitor structure on a substrate. The capacitor structure includes a first electrode structure, a second electrode structure, and a capacitor dielectric layer. The first electrode structure includes first horizontal electrode portions apart from each other in a first direction perpendicular to the substrate and a first conductive pillar connected to each of the first horizontal electrode portions and extending in the first direction. The second electrode structure includes a second conductive pillar extending through the first horizontal electrode portions in the first direction and second horizontal electrode portions apart from each other in the first direction on a side wall of the second conductive pillar and alternately arranged with the first horizontal electrode portions. The capacitor dielectric layer is between the side wall of the second conductive pillar and the first horizontal electrode portions.

### CROSS-REFERENCE TO RELATED APPLICATION

This application claims priority under 35 U.S.C. § 119 to Korean Patent Application No. 10-2023-0121274, filed on Sep. 12, 2023, in the Korean Intellectual Property Office, the disclosure of which is incorporated by reference herein in its entirety.

### BACKGROUND

According to the developments of electronic devices, semiconductor devices, such as integrated circuit devices or image sensors, have been highly integrated and miniaturized. Along with the high integration and miniaturization of semiconductor devices, integration and miniaturization of passive devices, such as capacitors, are also desired. For example, a capacitor having a high capacitance with a relatively decreased area is desired for an image sensor having high resolution, among other uses.

### SUMMARY

The present disclosure relates to semiconductor devices, including a semiconductor device including a capacitor structure having improved capacitance.

In general, according to some aspects, a semiconductor device includes a capacitor structure arranged on a substrate and including a first electrode structure including a plurality of first horizontal electrode portions apart from each other in a first direction perpendicular to an upper surface of the substrate and a first conductive pillar connected to each of the plurality of first horizontal electrode portions and extending in the first direction, a second electrode structure including a second conductive pillar penetrating through the plurality of first horizontal electrode portions and extending in the first direction and a plurality of second horizontal electrode portions apart from each other in the first direction on a side wall of the second conductive pillar and alternately arranged with the plurality of first horizontal electrode portions, and a capacitor dielectric layer arranged between the side wall of the second conductive pillar and the plurality of first horizontal electrode portions and on an upper surface, a side surface, and a bottom surface of each of the plurality of second horizontal electrode portions.

In general, according to some aspects, a semiconductor device includes a capacitor structure arranged on a substrate and including a first electrode structure including a plurality of first horizontal electrode portions apart from each other in a first direction perpendicular to an upper surface of the substrate, a plurality of mold insulating layers alternately arranged with the plurality of first horizontal electrode portions and respectively including a plurality of openings at a position at which the plurality of mold insulating layers overlap each other in the first direction, and a first conductive pillar connected to each of the plurality of first horizontal electrode portions and extending in the first direction, a second electrode structure including a second conductive pillar penetrating through the plurality of first horizontal electrode portions and extending in the first direction and a plurality of second horizontal electrode portions apart from each other in the first direction on a side wall of the second conductive pillar and arranged in the plurality of openings, respectively, and a capacitor dielectric layer arranged between the first electrode structure and the second electrode structure and including portions arranged on an upper surface, a side surface, and a bottom surface of each of the plurality of second horizontal electrode portions, in the plurality of openings.

In general, according to some aspects, a semiconductor device includes a semiconductor substrate on which a plurality of pixel areas are defined, each pixel area including a photovoltaic area, and a capacitor structure arranged on the semiconductor substrate and including a first electrode structure including a plurality of first horizontal electrode portions apart from each other in a first direction perpendicular to an upper surface of the substrate and a first conductive pillar connected to each of the plurality of first horizontal electrode portions and extending in the first direction, a second electrode structure including a second conductive pillar penetrating through the plurality of first horizontal electrode portions and extending in the first direction and a plurality of second horizontal electrode portions apart from each other in the first direction on a side wall of the second conductive pillar and alternately arranged with the plurality of first horizontal electrode portions, and a capacitor dielectric layer arranged between the side wall of the second conductive pillar and the plurality of first horizontal electrode portions and on an upper surface, a side surface, and a bottom surface of each of the plurality of second horizontal electrode portions.

### BRIEF DESCRIPTION OF THE DRAWINGS

Implementations will be more clearly understood from the following detailed description taken in conjunction with the accompanying drawings.

FIG. 1 is a perspective view of an example of a semiconductor device.

FIG. 2 is an example cross-sectional view of the semiconductor device of FIG. 1.

FIG. 3 is an example enlarged view of a region CX1 of FIG. 2.

FIGS. 4 to 7 are plan views of various planar layouts of an example of a first electrode structure and an example of a second electrode structure.

FIG. 8 is a cross-sectional view of an example of a semiconductor device.

FIG. 9 is an example enlarged view of a region CX1 of FIG. 8.

FIG. 10 is a cross-sectional view of an example of a semiconductor device.

FIG. 11 is an example enlarged view of a region CX1 of FIG. 10.

FIG. 12 is a cross-sectional view of another example of a semiconductor device.

FIG. 13 is a cross-sectional view of another example of a semiconductor device.

FIG. 14 is a cross-sectional view of another example of a semiconductor device.

FIG. 15 is a cross-sectional view of another example of a semiconductor device.

FIG. 16 is a cross-sectional view of another example of a semiconductor device.

FIGS. 17A, 17B, 18A, 18B, 19A, 19B, 20A, 20B, 21, 22A, 22B, 23A, 23B, and 24 are schematic views showing an example of a method of manufacturing a semiconductor device.

FIGS. 25 to 28 are schematic views showing another example of a method of manufacturing a semiconductor device.

### DETAILED DESCRIPTION

Hereinafter, implementations will be described in detail by referring to the accompanying drawings.

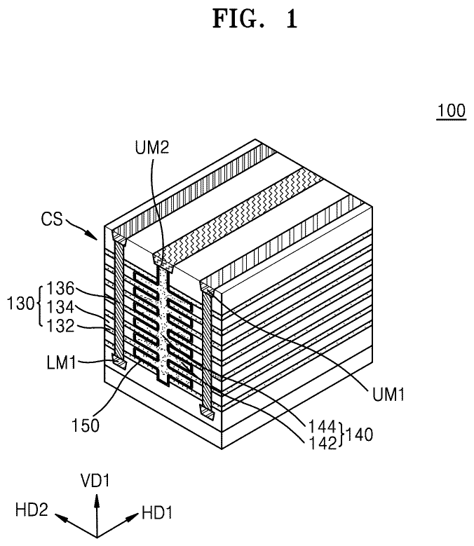

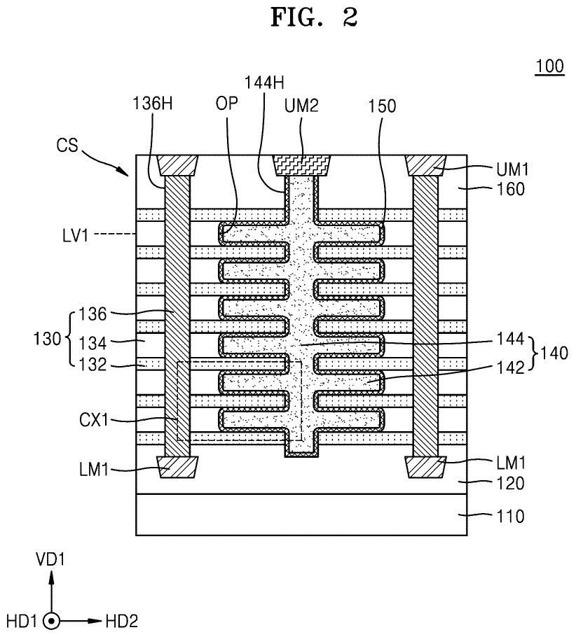

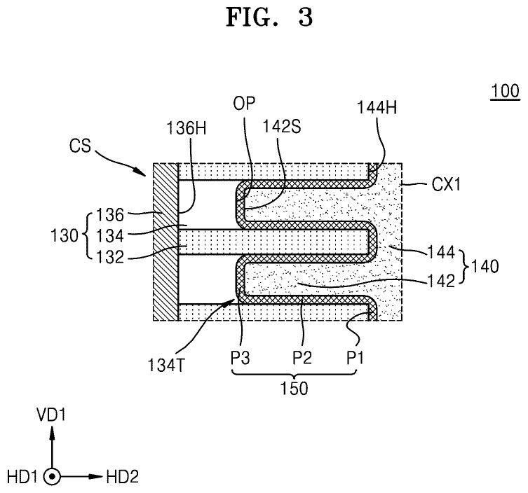

FIG. 1 is a perspective view of an example of a semiconductor device 100. FIG. 2 is an example cross-sectional view of the semiconductor device 100 of FIG. 1. FIG. 3 is an example enlarged view of a region CX1 of FIG. 2.

Referring to FIGS. 1 to 3, the semiconductor device 100 may include a substrate 110 and a capacitor structure CS arranged on the substrate 110. The capacitor structure CS may include a first electrode structure 130 having a three-dimensional structure, a second electrode structure 140 having a three-dimensional structure, and a capacitor dielectric layer 150 arranged between the first electrode structure 130 and the second electrode structure 140.

A lower structure 120 may be arranged on the substrate 110. The substrate 110 may include, for example, a semiconductor material, such as silicon, germanium, SiC, GaAs, InAs, and InP. Various individual devices may be arranged on the substrate 110. The individual devices may include various microelectronic devices, for example, a metal-oxide-semiconductor field effect transistor (MOSFET) such as a complementary metal-insulator-semiconductor (CMOS) transistor, system large scale integration (LSI), an image sensor, an active device, a passive device, etc.

The lower structure 120 may be arranged on the substrate 110 to cover the individual devices. The lower structure 120 may further include a conductive plug or an interconnect layer electrically connected to the individual devices and/or the substrate 110. In some implementations, the lower structure 120 may include insulating layers arranged at a plurality of vertical levels to cover the individual devices and surround the conductive plug or the interconnect layer.

A first lower conductive line LM1 may be arranged to be covered by the lower structure 120 and, for example, may extend in a first horizontal direction HD1. The first lower conductive line LM1 may be a connection line for providing a power supply and/or a signal to the first electrode structure 130 of the capacitor structure CS. In some implementations, the first lower conductive line LM1 may include at least one of TiN, TaN, WN, MON, NbN, CON, Ti, Ta, W, Ru, Mo, Nb, Co, and a silicide thereof.

The first electrode structure 130 may be arranged on the lower structure 120. The first electrode structure 130 may include a plurality of first horizontal electrode portions 132, a plurality of first mold insulating layers 134, and a first conductive pillar 136. The plurality of first horizontal electrode portions 132 and the plurality of first mold insulating layers 134 may be alternately arranged in a vertical direction VD1, and the first conductive pillar 136 may penetrate through the plurality of first horizontal electrode portions 132 and the plurality of first mold insulating layers 134 and may extend in the vertical direction VD1.

In some implementations, the plurality of first horizontal electrode portions 132 may include a semiconductor material, such as polysilicon, germanium, or silicon germanium. For example, the plurality of first horizontal electrode portions 132 may include doped or non-doped polysilicon. The plurality of first mold insulating layers 134 may include an insulating material. For example, the plurality of first mold insulating layers 134 may include at least one of silicon nitride, silicon oxynitride, silicon oxide, and silicon carbon oxide.

In some implementations, the plurality of first horizontal electrode portions 132 and the plurality of first mold insulating layers 134 may include materials having etch selectivities with respect to each other. In some implementations, the plurality of first horizontal electrode portions 132 may include polysilicon, and the plurality of first mold insulating layers 134 may include silicon nitride.

The first conductive pillar 136 may be arranged in a first vertical hole 136H penetrating through the plurality of first horizontal electrode portions 132 and the plurality of first mold insulating layers 134, and a bottom portion of the first conductive pillar 136 may be connected to the first lower conductive line LM1. Side wall portions of the first conductive pillar 136 may be surrounded by the plurality of first horizontal electrode portions 132, and the plurality of first horizontal electrode portions 132 may be electrically connected to the first lower conductive line LM1 through the first conductive pillar 136. In some implementations, the first conductive pillar 136 may include at least one of TiN, TaN, WN, MON, NbN, CON, Ti, Ta, W, Ru, Mo, Nb, Co, and a silicide thereof.

The plurality of first mold insulating layers 134 may include a plurality of openings OP, respectively, and the plurality of openings OP may be arranged to vertically overlap each other. For example, a second vertical hole 144H penetrating through the plurality of first horizontal electrode portions 132 and the plurality of first mold insulating layers 134 alternately stacked in the vertical direction VD1 may be formed and portions of the plurality of first mold insulating layer 134, the portions being exposed by the second vertical hole 144H, may be removed in a lateral direction by a pull-back process, and thus, the plurality of openings OP may be formed. In this pull-back process, the plurality of first horizontal electrode portions 132 may not be removed or damaged and may remain, and in some implementations, the plurality of openings OP may be formed to have a shape forming a concentric circle with the second vertical hole 144H.

The second electrode structure 140 may include a plurality of second horizontal electrode portions 142 and a second conductive pillar 144. The plurality of second horizontal electrode portions 142 may be arranged in the plurality of openings OP. Accordingly, the plurality of second horizontal electrode portions 142 may be surrounded by the plurality of first mold insulating layers 134 in the plurality of openings OP. For example, each of the plurality of second horizontal electrode portions 142 may be arranged in the opening OP of the first mold insulating layer 134 corresponding to each of the plurality of second horizontal electrode portions, and each of the plurality of second horizontal electrode portions 142 may be arranged at the same vertical level as the first mold insulating layer 134 corresponding to each of the plurality of second horizontal electrode portions 142. For example, as illustrated in FIG. 2, the number of first mold insulating layers 134 stacked in the vertical direction VD1 may be the same as the number of second horizontal electrode portions 142 stacked in the vertical direction VD1.

The second conductive pillar 144 may penetrate through the plurality of first horizontal electrode portions 132 and may be arranged in the second vertical hole 144H extending in the vertical direction VD1. The second conductive pillar 144 may extend in the vertical direction VD1, and the plurality of second horizontal electrode portions 142 may be arranged on a side wall of the second conductive pillar 144 to be apart from each other in the vertical direction VD1. The second conductive pillar 144 may have a bottom surface at a lower level than a bottom surface of the lowermost second horizontal electrode portion 142, and a bottom portion of the second conductive pillar 144 may be surrounded by the lower structure 120.

In some implementations, the plurality of second horizontal electrode portions 142 and the second conductive pillar 144 may include at least one of TiN, TaN, WN, MON, NbN, CON, Ti, Ta, W, Ru, Mo, Nb, Co, and a silicide thereof.

In some implementations, the second conductive pillar 144 may be integrally formed with the plurality of second horizontal electrode portions 142. For example, the second conductive pillar 144 may be formed by the same formation process as the plurality of second horizontal electrode portions 142. For example, by filling the second vertical hole 144H and the plurality of openings OP with a conductive material, the second conductive pillar 144 and the plurality of second horizontal electrode portions 142 may be formed by the same operation of the process. For example, portions of a material layer formed of the conductive material, the portions filling the plurality of openings OP and extending in a horizontal direction, may be referred to as the plurality of second horizontal electrode portions 142, and portions of the material layer formed of the conductive material, the portions filling the second vertical hole 144H and extending in the vertical direction VD1, may be referred to as the second conductive pillar 144. For example, the second conductive pillar 144 may form a continual material layer with the plurality of second horizontal electrode portions 142.

The capacitor dielectric layer 150 may be arranged between the first electrode structure 130 and the second electrode structure 140. The capacitor dielectric layer 150 may include a first portion P1, a second portion P2, and a third portion P3.

The capacitor dielectric layer 150 may include at least one selected from a high-k dielectric material having a higher dielectric constant than silicon oxide and a ferroelectric material. In some implementations, the capacitor dielectric layer 150 may include at least one material selected from among HfO, HfSiO, HfON, HfSiON, LaO, LaAlO, ZrO, ZrSiO, ZrON, ZrSiON, TaO, TiO, BaSrTiO, BaTiO, PbZrTiO, SrTaBiO, BiFcO, SrTiO, YO, AlO, or PbScTaO.

The first portion P1 of the capacitor dielectric layer 150 may be arranged on a side wall of the second vertical hole 144H and, for example, may be arranged between a side wall of the second conductive pillar 144 and side walls of the plurality of first horizontal electrode portions 132. For example, the first portion P1 of the capacitor dielectric layer 150 may extend on the side wall of the second conductive pillar 144 in the vertical direction VD1.

The second portion P2 of the capacitor dielectric layer 150 may be arranged in the plurality of openings OP and, for example, may be arranged on an upper surface and a bottom surface of each of the plurality of second horizontal electrode portions 142. For example, the second portion P2 of the capacitor dielectric layer 150 may be arranged between the upper surface of one second horizontal electrode portion 142 and a bottom surface of one first horizontal electrode portion 132, which is arranged directly above the one second horizontal electrode portion 142, and may be arranged between the bottom surface of the one second horizontal electrode portion 142 and an upper surface of another first horizontal electrode portion 132, which is arranged directly below the one second horizontal electrode portion 142. The second portion P2 of the capacitor dielectric layer 150 may extend on the upper surface and the bottom surface of each of the plurality of second horizontal electrode portions 142 in the horizontal direction.

The third portion P3 of the capacitor dielectric layer 150 may be arranged in the plurality of openings OP and may be arranged between the plurality of first mold insulating layers 134 and the plurality of second horizontal electrode portions 142. For example, the third portion P3 of the capacitor dielectric layer 150 may be in contact with a side surface 142S of each of the plurality of second horizontal electrode portions 142 and may extend in the vertical direction VD1.

In some implementations, as the first portion P1 of the capacitor dielectric layer 150 may be arranged between the side walls of the first horizontal electrode portions 132 and the side wall of the second conductive pillar 144, the first portion P1 of the capacitor dielectric layer 150 may function as a first effective capacitor area exhibiting a capacitance, and as the second portion P2 of the capacitor dielectric layer 150 may be arranged between the plurality of first horizontal electrode portions 132 and the plurality of second horizontal electrode portions 142 alternately arranged with each other, the second portion P2 of the capacitor dielectric layer 150 may function as a second effective capacitor area exhibiting a capacitance. In some implementations, a width in the horizontal direction (for example, a width in a second horizontal direction HD2) of the second horizontal electrode portions 142 may be greater than a thickness (for example, a thickness in the vertical direction VD1) of the second horizontal electrode portions 142 and/or a thickness (for example, a thickness in the vertical direction VD1) of the first horizontal electrode portions 132, and an area of the second effective capacitor area may be greater than an area of the first effective capacitor area. In some implementations, according to the number of first horizontal electrode portions 132 and the number of second horizontal electrode portions 142, the area of the second effective capacitor area may be increased, and the capacitor structure CS may have relatively increased capacitance.

In some implementations, the plurality of openings OP respectively included in the plurality of first mold insulating layers 134 may be formed such that at least a portion of each of the plurality of openings OP may have a curved shape. For example, with respect to the opening OP arranged in a space between one first mold insulating layer 134, one first horizontal electrode portion 132 arranged directly above the one first mold insulating layer 134, and another first horizontal electrode portion 132 arranged directly below the one first mold insulating layer 134, a first portion of a side wall of the opening OP, arranged to be adjacent to the one first horizontal electrode portion 132, and a second portion of the side wall of the opening OP, arranged to be adjacent to the other first horizontal electrode portion 132, may have curved profiles, and the first mold insulating layer 134 may include a tail portion 134T corresponding to the curved profiles of the opening OP. The first mold insulating layers 134 may include the tail portions 134T, and the capacitor dielectric layer 150 may be arranged to conformally cover the tail portions 134T, and thus, the side surface 142S of each of the second horizontal electrode portions 142 may have a round shape.

In some implementations, unlike what is illustrated in FIG. 3, the plurality of openings OP respectively included in the plurality of first mold insulating layer 134 may be formed to have substantially vertical profiles and the tail portions 134T may not be formed in the first mold insulating layers 134. In this case, the side surfaces 142S of the second horizontal electrode portions 142 may also have substantially vertical profiles according to the vertical profiles of the plurality of openings OP.

An upper insulating layer 160 may be arranged on the uppermost first horizontal electrode portion 132. A first upper conductive line UM1 and a second upper conductive line UM2 may be arranged in an opening extending into the upper insulating layer 160.

The first upper conductive line UM1 may be connected to the first conductive pillar 136 of the first electrode structure 130 and, for example, may extend on the first conductive pillar 136 in the first horizontal direction HD1. The first upper conductive line UM1 may be a connection line for providing a power supply and/or a signal to the first electrode structure 130 of the capacitor structure CS.

The second upper conductive line UM2 may be connected to the second conductive pillar 144 of the second electrode structure 140 and, for example, may extend on the second conductive pillar 144 in the first horizontal direction HD1. The second upper conductive line UM2 may be arranged to be apart from the first upper conductive line UM1. The second upper conductive line UM2 may be a connection line for providing a power supply and/or a signal to the second electrode structure 140 of the capacitor structure CS.

In some implementations, the first upper conductive line UM1 and the second upper conductive line UM2 may include at least one of TiN, TaN, WN, MON, NbN, CON, Ti, Ta, W, Ru, Mo, Nb, Co, and a silicide thereof.

FIG. 2 illustrates that a bottom surface of the first conductive pillar 136 may be connected to the first lower conductive line LM1 and am upper surface of the first conductive pillar 136 may be connected to the first upper conductive line UM1. However, in some implementations, the first conductive pillar 136 may be connected to the first upper conductive line UM1 and the first lower conductive line LM1 may be omitted, or the first conductive pillar 136 may be connected to the first lower conductive line LM1 and the first upper conductive line UM1 may be omitted.

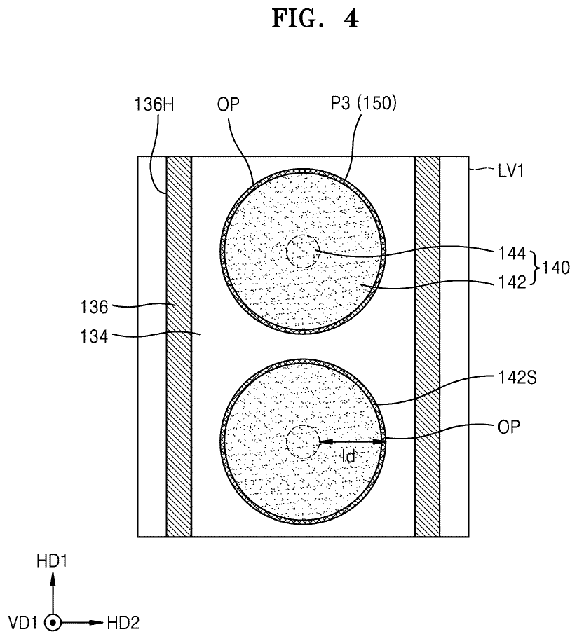

FIGS. 4 to 7 are plan views of various planar layouts of an example of the first electrode structure 130 and an example of the second electrode structure 140. FIGS. 4 to 7 correspond to horizontal cross-sectional views at a first vertical level LV1 of FIG. 2.

Referring to FIG. 4, the first vertical hole 136H may have a trench shape extending in the first horizontal direction HD1, and the first conductive pillar 136 arranged in the first vertical hole 136H may extend in the first horizontal direction HD1. For example, the first conductive pillar 136 may have a bar-shaped horizontal section extending in the first horizontal direction HD1.

The second conductive pillar 144 may have a circular horizontal section, and the second horizontal electrode portion 142 may have an annular horizontal section. For example, the side surface 142S of the second horizontal electrode portion 142 may form a concentric circle with the second conductive pillar 144. For example, lateral distances ld in a radial direction from the side surface 142S of the second horizontal electrode portion 142 to the second conductive pillar 144 may be identical.

For example, as illustrated in FIG. 2, the second vertical hole 144H penetrating through the plurality of first horizontal electrode portions 132 and the plurality of first mold insulating layers 134 alternately stacked in the vertical direction VD1 may be formed, and portions of the plurality of first mold insulating layers 134, the portions being exposed by the second vertical hole 144H, may be removed in a lateral direction by a pull-back process to form the plurality of openings OP. By this pull-back process, the plurality of openings OP may be formed to have a shape forming a concentric circle with the second vertical hole 144H, and the second horizontal electrode portions 142 filling the plurality of openings OP may also have a shape forming a concentric circle with the second conductive pillar 144 arranged in the second vertical hole 144H.

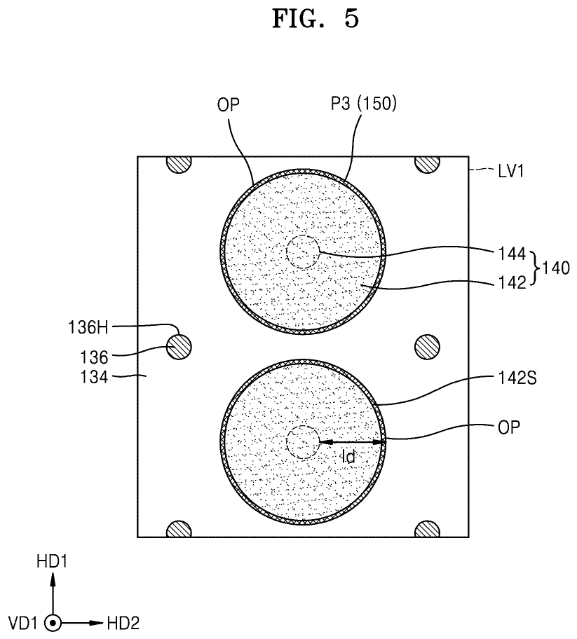

Referring to FIG. 5, the first vertical hole 136H may have a circular horizontal section, and the first conductive pillar 136 arranged in the first vertical hole 136H may have a circular horizontal section. The second conductive pillar 144 may have a circular horizontal section, and each of the second horizontal electrode portions 142 may have an annular horizontal section.

FIG. 5 illustrates that the first conductive pillar 136 may be arranged to be offset from the second conductive pillar 144 in the first horizontal direction HD1. However, unlike the illustration of FIG. 5, the second conductive pillar 144 may have the same position as the first conductive pillar 136 in the first horizontal direction HD1 and may be arranged to be apart from the first conductive pillar 136 in the second horizontal direction HD2.

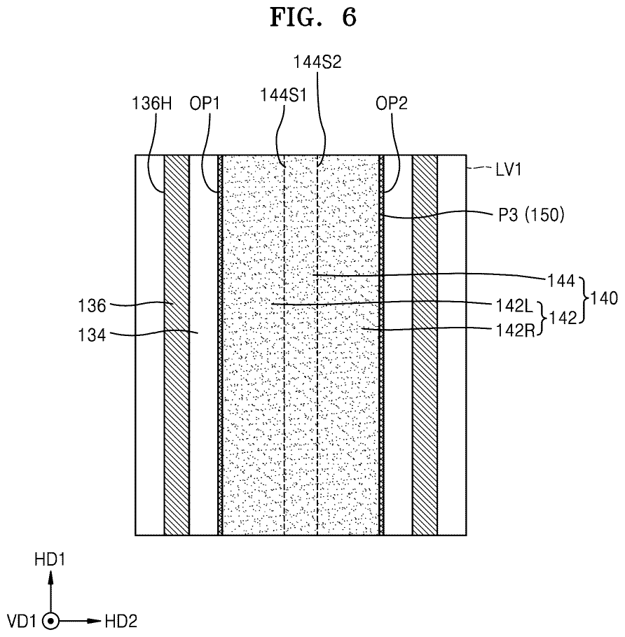

Referring to FIG. 6, the first vertical hole 136H may have a trench shape extending in the first horizontal direction HD1, and the first conductive pillar 136 arranged in the first vertical hole 136H may extend in the first horizontal direction HD1.

The second conductive pillar 144 may have a bar shape extending in the first horizontal direction HD1. The second horizontal electrode portion 142 may include a first sub-electrode portion 142L arranged on a first side surface 144S1 of the second conductive pillar 144 and a second sub-electrode portion 142R arranged on a second side surface 144S2 of the second conductive pillar 144. For example, the first sub-electrode portion 142L and the second sub-electrode portion 142R may be formed to have a symmetrical shape with respect to each other.

In some implementations, a width in the second horizontal direction HD2 from the first side surface 144S1 of the second conductive pillar 144 to a side surface of the first sub-electrode portion 142L (for example, a side surface of the first sub-electrode portion 142L, the side surface facing the first mold insulating layer 134) may be the same as a width in the second horizontal direction HD2 from the second side surface 144S2 of the second conductive pillar 144 to a side surface of the second sub-electrode portion 142R (for example, a side surface of the second sub-electrode portion 142R, the side surface facing the first mold insulating layer 134).

For example, as illustrated in FIG. 2, the second vertical hole 144H penetrating through the plurality of first horizontal electrode portions 132 and the plurality of first mold insulating layers 134 alternately stacked in the vertical direction VD1 may be formed, and portions of the plurality of first mold insulating layers 134, the portions being exposed by the second vertical hole 144H, may be removed in a lateral direction by a pull-back process to form the plurality of openings OP. The second vertical hole 144H may have a trench shape extending in the first horizontal direction HD1, and here, the portions of the plurality of first mold insulating layers 134, the portions being arranged at both sides of the second vertical hole 144H, may be removed by the pull-back process.

In some implementations, each of the plurality of openings OP may include a first side wall and a second side wall, the first side walls of the plurality of openings OP may be arranged to be parallel with a first side wall of the second vertical hole 144H, and the second side walls of the plurality of openings OP may be arranged to be parallel with a second side wall of the second vertical hole 144H. For example, the first side walls of the plurality of openings OP may be arranged to be parallel with the first side surface 144S1 of the second conductive pillar 144, and the second side walls of the plurality of openings OP may be arranged to be parallel with the second side surface 144S2 of the second conductive pillar 144.

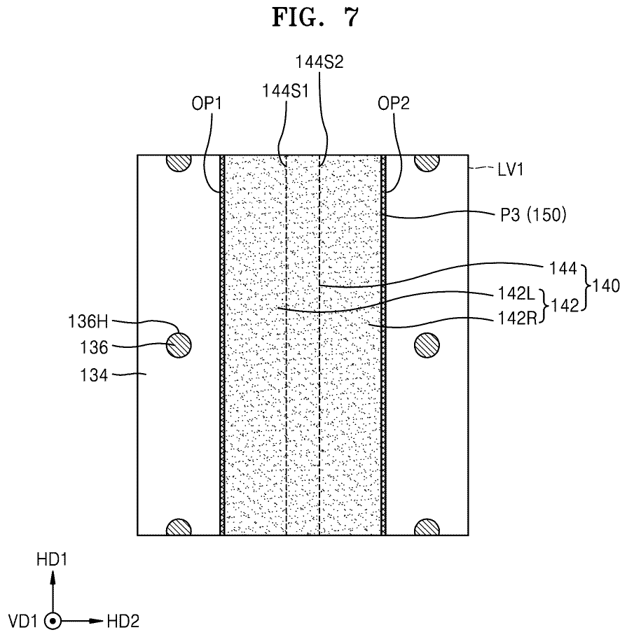

Referring to FIG. 7, the first vertical hole 136H may have a circular horizontal section, and the first conductive pillar 136 arranged in the first vertical hole 136H may have a circular horizontal section. The second conductive pillar 144 may have a bar shape extending in the first horizontal direction HD1. Each of the second horizontal electrode portions 142 may include the first sub-electrode portion 142L arranged on the first side surface 144S1 of the second conductive pillar 144 and the second sub-electrode portion 142R arranged on the second side surface 144S2 of the second conductive pillar 144.

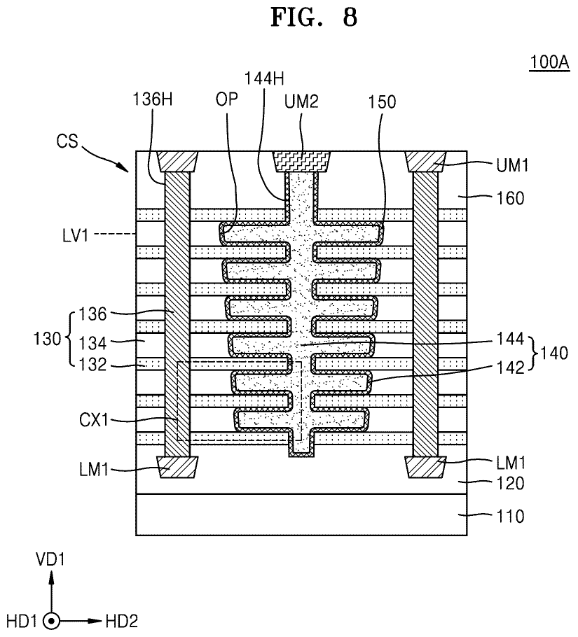

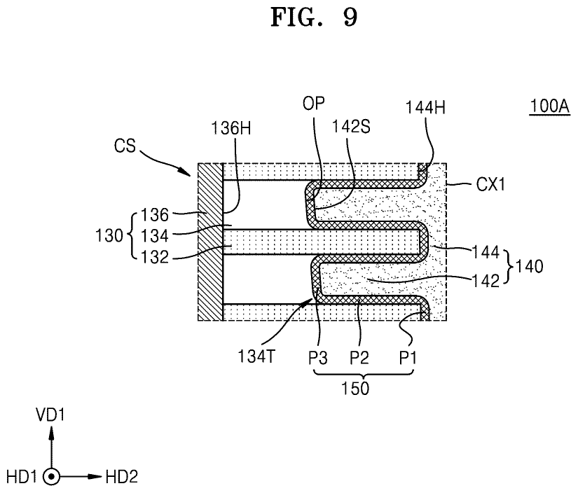

FIG. 8 is a cross-sectional view of an example of a semiconductor device 100A. FIG. 9 is an example enlarged view of a region CX1 of FIG. 8.

Referring to FIGS. 8 and 9, the second vertical hole 144H may have a tapered shape in which an upper width of the second vertical hole 144H is greater than a lower width of the second vertical hole 144H.

In some implementations, the second vertical hole 144H penetrating through the plurality of first horizontal electrode portions 132 and the plurality of first mold insulating layers 134 alternately stacked in a vertical direction VD1 may be formed, and portions of the plurality of first mold insulating layers 134, the portions being exposed by the second vertical hole 144H, may be removed in a lateral direction by a pull-back process to form the plurality of openings OP.

In the process of forming the second vertical hole 144H, an upper portion of the second vertical hole 144H may be exposed to an etch atmosphere relatively more than a lower portion of the second vertical hole 144H, and thus, an upper width of the second vertical hole 144H may become greater than a lower width of the second vertical hole 144H.

Also, when the portions of the plurality of first mold insulating layers 134, the portions being arranged at both sides of the second vertical hole 144H, are removed by the pull-back process, the portions of the first mold insulating layers 134, the portions being adjacent to the upper portion of the second vertical hole 144H, may be exposed to the etch atmosphere more than the portions of the first mold insulating layers 134, the portions being adjacent to the lower portion of the second vertical hole 144H. In this case, an etch amount of the first mold insulating layers 134 adjacent to the upper portion of the second vertical hole 144H may be greater than an etch amount of the first mold insulating layers 134 adjacent to the lower portion of the second vertical hole 144H, and widths of the openings OP of the first mold insulating layers 134 adjacent to the upper portion of the second vertical hole 144H may be greater than widths of the openings OP of the first mold insulating layers 134 adjacent to the lower portion of the second vertical hole 144H.

In some implementations, a width in a horizontal direction of one second horizontal electrode portion 142 from among the plurality of second horizontal electrode portions 142, the one second horizontal electrode portion 142 being adjacent to the upper portion of the second vertical hole 144H, may be greater than a width in the horizontal direction of another second horizontal electrode portion 142 from among the plurality of second horizontal electrode portions 142, the other second horizontal electrode portion 142 being adjacent to the lower portion of the second vertical hole 144H. For example, a width in the horizontal direction of the second horizontal electrode portion 142 arranged on the first vertical level LV1 may be greater than a width in the horizontal direction of the second horizontal electrode portion 142 arranged on a vertical level lower than the first vertical level LV1.

In some implementations, the second vertical hole 144H may have an inclined side wall, and at least a portion of each of the plurality of openings OP may also have an inclined side wall profile. Accordingly, at least a portion of the side surface 142S of each of the plurality of second horizontal electrode portions 142 arranged in the openings OP, respectively, may have an inclined profile.

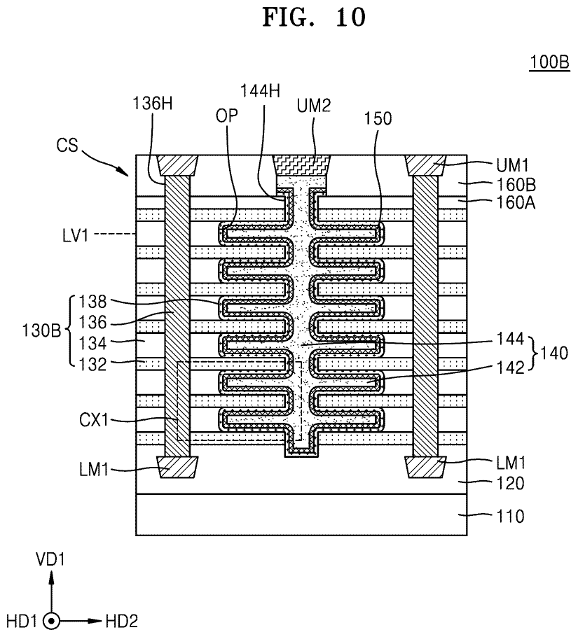

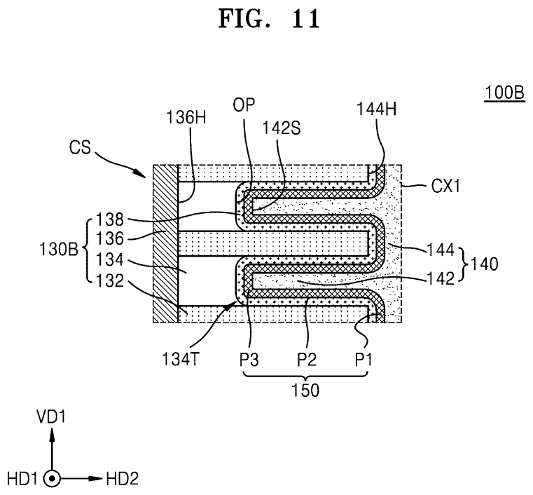

FIG. 10 is a cross-sectional view of an example of a semiconductor device 100B. FIG. 11 is an example enlarged view of a region CX1 of FIG. 10.

Referring to FIGS. 10 and 11, a first electrode structure 130B may include the plurality of first horizontal electrode portions 132, the plurality of first mold insulating layers 134, the first conductive pillar 136, and a conductive electrode layer 138.

In some implementations, the conductive electrode layer 138 may be arranged along a side wall of the second vertical hole 144H and an inner wall of each of the openings OP and may be arranged between the plurality of first horizontal electrode portions 132 and the capacitor dielectric layer 150 and between the plurality of first mold insulating layers 134 and the capacitor dielectric layer 150. For example, the conductive electrode layer 138 may be conformally arranged on the first portion P1, the second portion P2, and the third portion P3 of the capacitor dielectric layer 150. Accordingly, the capacitor dielectric layer 150 may not be in contact with the plurality of first horizontal electrode portions 132 or the plurality of first mold insulating layers 134 and may be arranged between the second electrode structure 140 and the conductive electrode layer 138.

In some implementations, the conductive electrode layer 138 may include at least one of titanium, tantalum, tungsten, molybdenum, niobium, titanium nitride, tantalum nitride, tungsten nitride, molybdenum nitride, and niobium nitride.

In some implementations, a first upper insulating layer 160A may be arranged on the uppermost first horizontal electrode portion 132, and a second upper insulating layer 160B may be arranged on the first upper insulating layer 160A. The second vertical hole 144H may penetrate through the first upper insulating layer 160A, the plurality of first horizontal electrode portions 132, and the plurality of first mold insulating layers 134 and may extend in a vertical direction VD1. The conductive electrode layer 138 may be arranged on the side wall of the second vertical hole 144H and the inner walls of the plurality of openings OP, and a portion of the conductive electrode layer 138 may extend onto an upper surface of the first upper insulating layer 160A.

In some implementations, the capacitor structure CS may be a metal-insulator-metal- semiconductor (MIMS)-type capacitor including the first horizontal electrode portions 132 and the conductive electrode layer 138 as electrodes of the first electrode structure 130B. For example, the conductive electrode layer 138 may be electrically connected to the first conductive pillar 136 through the plurality of first horizontal electrode portions 132 which are in contact with the conductive electrode layer 138. The conductive electrode layer 138 may function as an effective electrode area of the first electrode structure 130B together with the plurality of first horizontal electrode portions 132. Also, the conductive electrode layer 138 may be arranged to conformally extend along the side wall of the second vertical hole 144H and the inner walls of the plurality of openings OP, and thus, all of the first portion P1, the side second portion P2, and the third portion P3 of the capacitor dielectric layer 150 may function effective capacitor areas. The semiconductor device 100B according to the implementations described above may have relatively increased capacitance.

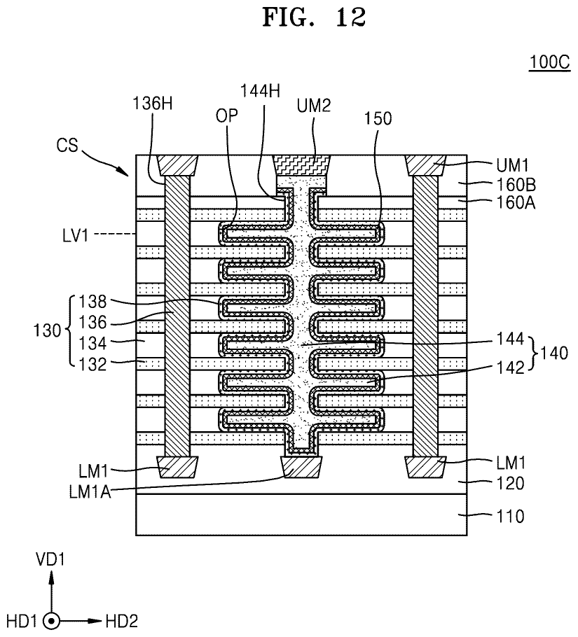

FIG. 12 is a cross-sectional view of another example of a semiconductor device 100C.

Referring to FIG. 12, a second lower conductive line LM1A may be arranged on the lower structure 120, and the second lower conductive line LM1A may be apart from the first lower conductive line LM1 and may extend in a first horizontal direction HD1. The second lower conductive line LM1A may be electrically connected to a bottom surface of the conductive electrode layer 138.

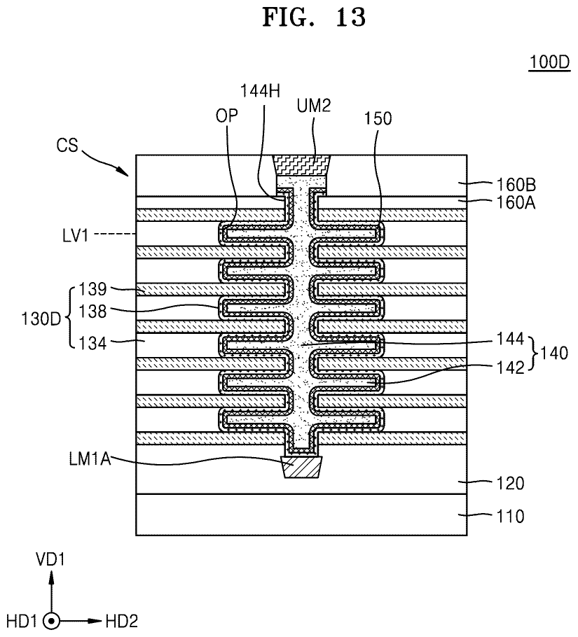

FIG. 13 is a cross-sectional view of another example of a semiconductor device 100D.

Referring to FIG. 13, a first electrode structure 130D may include the plurality of first mold insulating layers 134, the conductive electrode layer 138, and a plurality of second mold insulating layers 139. The plurality of first mold insulating layers 134 and the plurality of second mold insulating layers 139 may be mold structures for defining a three-dimensional shape of the conductive electrode layer 138. The plurality of first mold insulating layers 134 may include the plurality of openings OP, and the conductive electrode layer 138 may be arranged on the inner walls of the plurality of openings OP.

For example, the plurality of first mold insulating layers 134 and the plurality of second mold insulating layers 139 may include materials having etch selectivities with respect to each other. For example, the plurality of first mold insulating layers 134 and the plurality of second mold insulating layers 139 may include at least one of silicon oxide, silicon nitride, silicon oxynitride, silicon carbide, and silicon carbon oxide. For example, the plurality of first mold insulating layers 134 may include silicon nitride, and the plurality of second mold insulating layers 139 may include silicon oxide.

The plurality of first mold insulating layers 134 may include the plurality of openings OP, respectively, and the plurality of openings OP may be arranged to vertically overlap each other. For example, the second vertical hole 144H penetrating through the plurality of first mold insulating layers 134 and the plurality of second mold insulating layers 139 alternately stacked in a vertical direction VD1 may be formed, and portions of the plurality of first mold insulating layers 134, the portions being exposed by the second vertical hole 144H, may be removed in a lateral direction by a pull-back process. Thus, the plurality of openings OP may be formed. In this pull-back process, the plurality of second mold insulating layers 139 may not be removed or damaged and may remain, and in some implementations, the plurality of openings OP may be formed to have a shape forming a concentric circle with the second vertical hole 144H.

The second electrode structure 140 may include the plurality of second horizontal electrode portions 142 and the second conductive pillar 144. The second conductive pillar 144 may extend in the second vertical hole 144H in the vertical direction VD1, and the plurality of second horizontal electrode portions 142 may be arranged on a side wall of the second conductive pillar 144 to extend in a horizontal direction.

The conductive electrode layer 138 and the capacitor dielectric layer 150 may be sequentially formed in the plurality of openings OP, and remaining portions of the plurality of openings OP may be filled by the plurality of second horizontal electrode portions 142. Accordingly, an effective capacitor area having a three-dimensional structure may be defined in the plurality of openings OP and the effective capacitor area may have a relatively increased area.

In some implementations, a planar shape of the second electrode structure 140 may be substantially the same as described with reference to FIGS. 4 to 7. In some implementations, as described with reference to FIGS. 4 and 5, the second conductive pillar 144 may have a circular horizontal sectional shape, and the plurality of second horizontal electrode portions 142 may have an annular horizontal sectional shape forming a concentric circle with the second conductive pillar 144. In some implementations, as described with reference to FIGS. 6 and 7, the second conductive pillar 144 may have a bar-shaped horizontal section extending in a first horizontal direction HD1, and the plurality of second horizontal electrode portions 142 may include the first sub-electrode portion 142L (see FIG. 6) arranged on a first side wall of the second conductive pillar 144 and the second sub-electrode portion 142R (see FIG. 6) arranged on a second side wall of the second conductive pillar 144.

The second lower conductive line LM1A may be arranged on the lower structure 120, and the second lower conductive line LM1A may extend in the first horizontal direction HD1. The second lower conductive line LM1A may be electrically connected to a bottom surface of the conductive electrode layer 138.

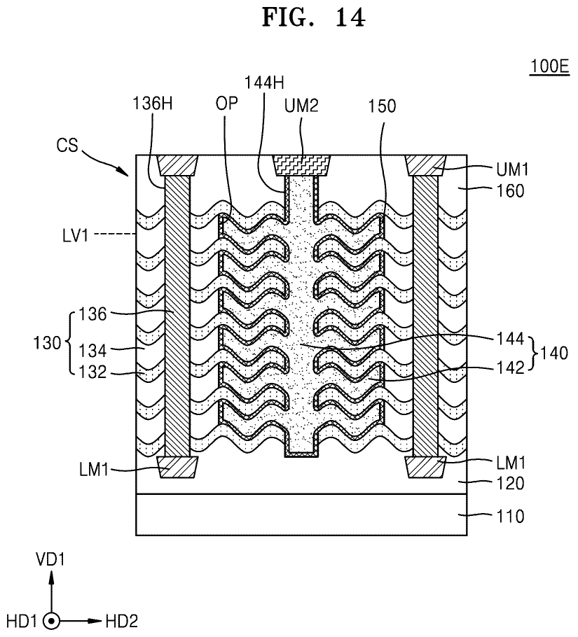

FIG. 14 is a cross-sectional view of another example of a semiconductor device 100E.

Referring to FIG. 14, the lower structure 120 may have a textured upper surface and may include, for example, a concavo-convex surface. The plurality of first horizontal electrode portions 132 and the plurality of first mold insulating layers 134 may have concavo-convex surfaces of a shape conforming to the concavo-convex surface of the lower structure 120, and the plurality of second horizontal electrode portions 142 arranged in the openings OP of the plurality of first mold insulating layers 134 may also have concavo-convex surfaces of a shape conforming to the concavo-convex surfaces of the plurality of first horizontal electrode portions 132. The capacitor dielectric layer 150 may be conformally arranged between the concavo-convex surfaces of the plurality of first horizontal electrode portions 132 and the concavo-convex surfaces of the plurality of second horizontal electrode portions 142.

In some implementations, the concavo-convex surface of the lower structure 120 may be formed by forming a mask pattern on the lower structure 120 and removing an upper portion of the lower structure 120 by using the mask pattern as an etch mask. Thereafter, the plurality of first horizontal electrode portions 132 and the plurality of first mold insulating layers 134 may be alternately and sequentially formed on the lower structure 120 having the concavo-convex surface, and thus, the plurality of first horizontal electrode portions 132 and the plurality of first mold insulating layers 134 may be formed to have a shape having the concavo-convex surfaces.

In some implementations, the lower structure 120 may have a flat upper surface, a template layer having a concavo-convex surface may further be formed between the lower structure 120 and the lowermost first horizontal electrode portion 132, and the plurality of first horizontal electrode portions 132 and the plurality of first mold insulating layers 134 may be alternately and sequentially formed on the template layer. Thus, the plurality of first horizontal electrode portions 132 and the plurality of first mold insulating layers 134 may be formed to have a shape having the concavo-convex surfaces.

In some implementations, because the plurality of first horizontal electrode portions 132 and the plurality of second horizontal electrode portions 142 may have the concavo-convex surfaces, an area of an effective capacitor area may be increased, and the capacitor structure CS may have relatively increased capacitance.

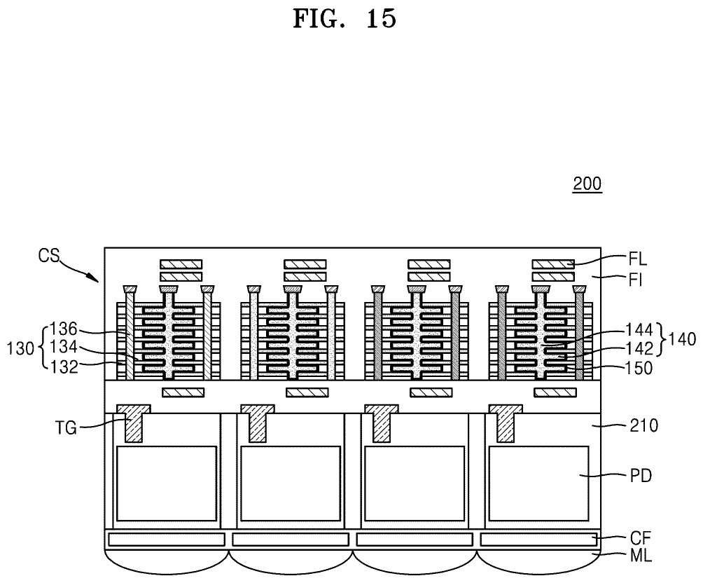

FIG. 15 is a cross-sectional view of another example of a semiconductor device 200. In FIG. 15, the same reference numerals as in FIGS. 1 to 14 may indicate the same elements.

Referring to FIG. 15, the semiconductor device 200 may be a global shutter type image sensor including a plurality of photovoltaic areas PD formed on a semiconductor substrate 210 and the capacitor structure CS arranged on a front surface of the semiconductor substrate 210.

A transmission gate TG may be arranged to extend into the semiconductor substrate 210 and may be configured to control a photoelectron stored in the photovoltaic areas PD. A pixel transistor may further be formed on the front surface of the semiconductor substrate 210 and the pixel transistor may be electrically connected to the capacitor structure CS, so that a charge transmitted from the photovoltaic area PD of each of pixel areas may be stored in the capacitor structure CS.

A front face interconnect layer FL and a front face insulating layer FI covering the capacitor structure CS may be arranged on the front face of the semiconductor substrate 210, and a color filter CF and a micro-lens ML may be arranged on a back face of the semiconductor substrate 210.

The capacitor structure CS may include the first electrode structure 130, the second electrode structure 140, and the capacitor dielectric layer 150, and the structure of the capacitor structure CS may include any one of the structures described with reference to FIGS. 1 to 15. In some implementations, the capacitor structure CS may be formed as a plurality, and the plurality of capacitor structures CS may be arranged to respectively correspond to the plurality of pixel areas formed on the semiconductor substrate 210.

In some implementations, the capacitor structure CS may have relatively increased capacitance with a relatively decreased area, and thus, the global shutter type image sensor including the capacitor structure CS may have high resolution and superb image quality.

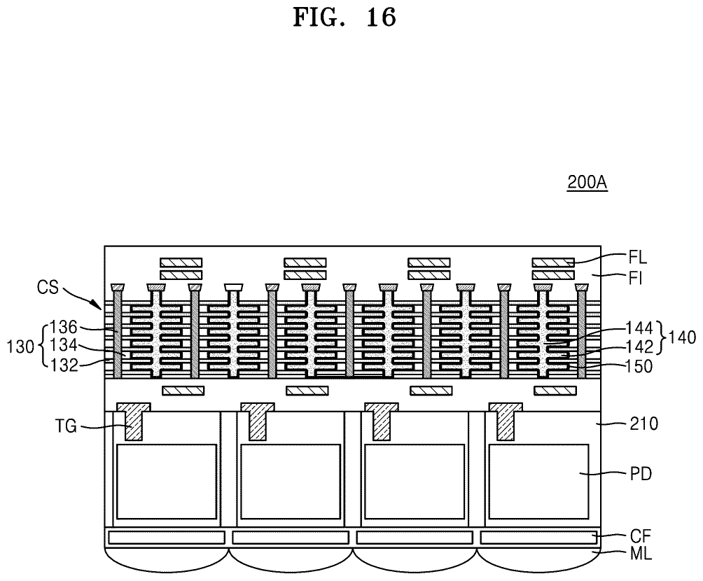

FIG. 16 is a cross-sectional view of another example of a semiconductor device 200A.

Referring to FIG. 16, the capacitor structure CS may be arranged on a plurality of pixels formed on the semiconductor substrate 210. For example, the first electrode structure 130 may be arranged to extend in a horizontal direction to vertically overlap the plurality of pixels (for example, to vertically overlap the plurality of photovoltaic areas PD), and the second electrode structure 140 may be arranged to penetrate through the first electrode structure 130. For example, the first electrode structure 130 may be a common electrode and may be commonly and electrically connected to the plurality of pixel areas. The second electrode structure 140 may be formed as a plurality, and at least one second electrode structure 140 may be electrically connected to each of pixel areas.

FIGS. 15 and 16 illustrate the image sensor including the capacitor structure CS. However, in some implementations, the capacitor structure CS may be integrated as an integrated circuit device including a memory device and/or a logic device. In some implementations, the capacitor structure CS may be included in the integrated circuit device including the logic device and may be used as a device control circuit, such as a power regulator of the logic device. For example, the capacitor structure CS may have relatively increased capacitance, and thus, noise of a power line and/or a signal line of the integrated circuit device may be reduced. In some implementations, the capacitor structure CS may be included in an electronic system such as a mobile electronic device and may be used as a backup power supply such as a battery back-up random-access memory (RAM). For example, the capacitor structure CS may have relatively increased capacitance, and thus, even when a momentary suspension of power of the electronic system such as the mobile electronic device occurs, stable operation of the system may be possible.

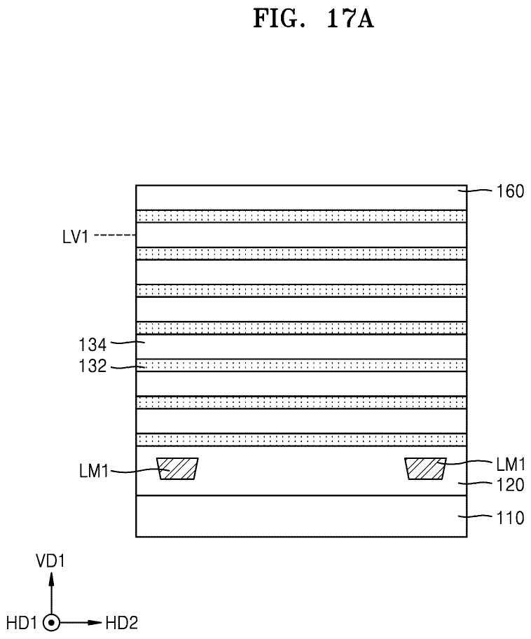

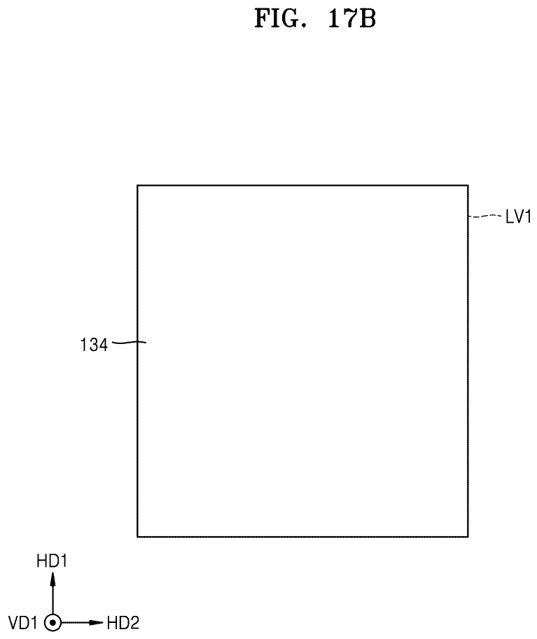

FIGS. 17A, 17B, 18A, 18B, 19A, 19B, 20A, 20B, 21, 22A, 22B, 23A, 23B, and 24 are schematic views showing an example of a method of manufacturing the semiconductor device 100. FIGS. 17A, 18A, 19A, 20A, 21, 22A, 23A, and 24 are cross-sectional views illustrated according to a process order, and FIGS. 17B, 18B, 19B, 20B, 22B, and 23B are horizontal cross-sectional views at the first vertical level LV1 of FIGS. 17A, 18A, 19A, 20A, 22A, and 23A.

Referring to FIGS. 17A and 17B, the lower structure 120 may be formed on the substrate 110, and the first lower conductive line LM1 surrounded by the lower structure 120 and extending in the first horizontal direction HD1 may be formed.

The plurality of first horizontal electrode portions 132 and the plurality of first mold insulating layers 134 may be alternately formed on the lower structure 120.

In some implementations, the plurality of first horizontal electrode portions 132 may be formed by using a semiconductor material, such as polysilicon, germanium, or silicon germanium, and the plurality of first mold insulating layers 134 may be formed by using at least one insulating material from among silicon nitride, silicon oxynitride, silicon oxide, and silicon carbon oxide. In some implementations, the plurality of first horizontal electrode portions 132 and the plurality of first mold insulating layers 134 may be formed by using materials having etch selectivities with respect to each other.

Thereafter, the upper insulating layer 160 may be formed on the uppermost first horizontal electrode portion 132.

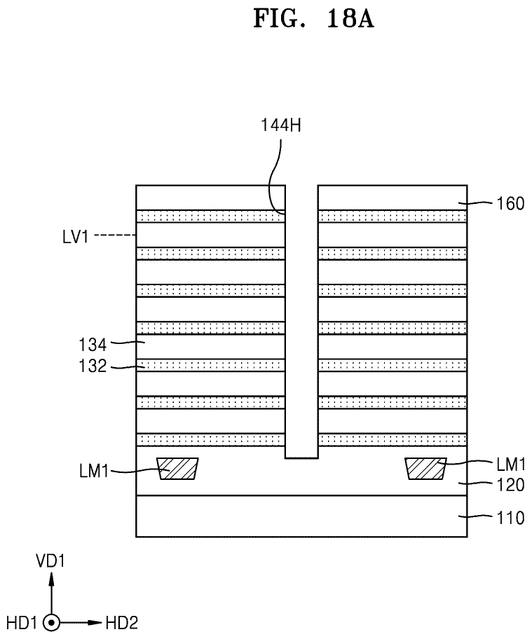

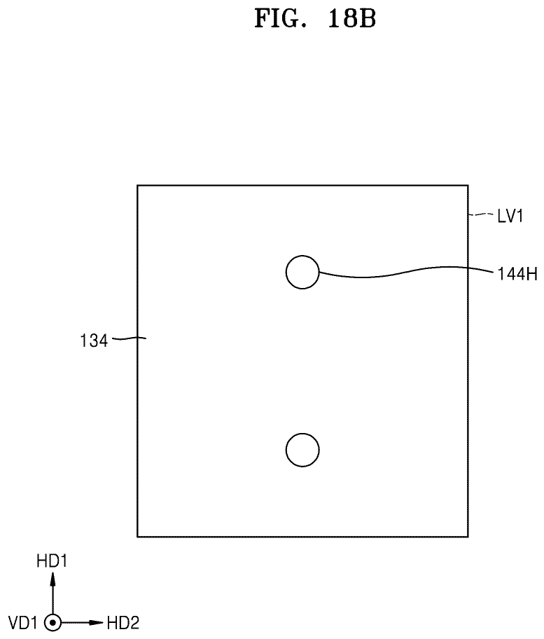

Referring to FIGS. 18A and 18B, a mask pattern may be formed on the upper insulating layer 160, and the mask pattern may be used as an etch mask to remove portions of the plurality of first horizontal electrode portions 132 and the plurality of first mold insulating layer 134 to form the second vertical hole 144H. The second vertical hole 144H may be arranged at a lower level than the lowermost first horizontal electrode portion 132 and may have a bottom portion covered by the lower structure 120.

In some implementations, as illustrated in FIG. 18B, the second vertical hole 144H may have a circular horizontal section. In some implementations, as illustrated in FIG. 7, the second vertical hole 144H may have a bar-shaped horizontal section extending in the first horizontal direction HD1.

FIG. 18A illustrates that the second vertical hole 144H may have a vertical side wall profile, and an upper width of the second vertical hole 144H may be substantially the same as a lower width of the second vertical hole 144H. In some implementations, according to an etch process condition, an upper portion of the second vertical hole 144H may be exposed to an etch atmosphere more than a lower portion of the second vertical hole 144H, and thus, the upper width of the second vertical hole 144H may be greater than the lower width of the second vertical hole 144H, and in this case, as described with reference to FIGS. 8 and 9, the second vertical hole 144H may have an inclined side wall.

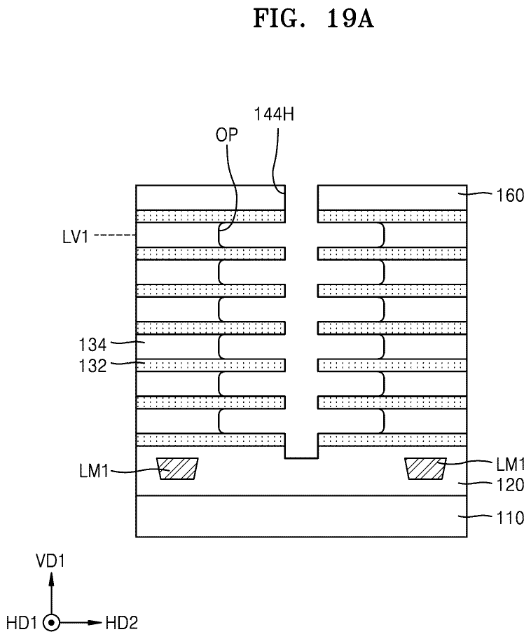

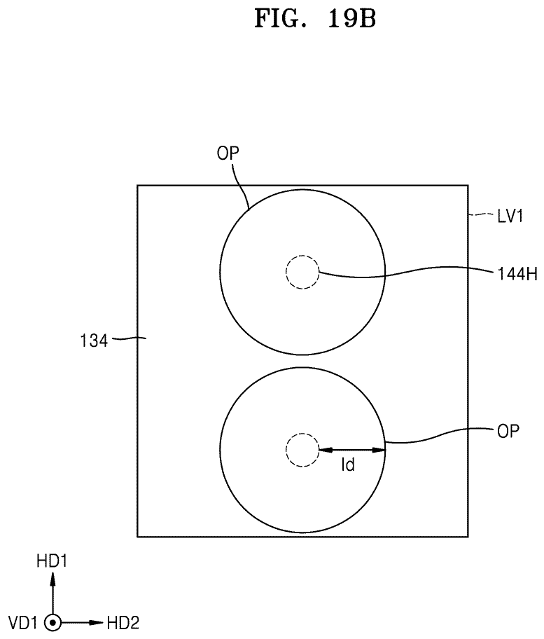

Referring to FIGS. 19A and 19B, portions of the plurality of first mold insulating layers 134, exposed through a side wall of the second vertical hole 144H, may be removed, and the plurality of openings OP may be formed. In some implementations, in a process for removing the portions of the plurality of first mold insulating layers 134, the plurality of first horizontal electrode portions 132 may rarely be removed and may remain.

In some implementations, the process for removing the portions of the plurality of first mold insulating layers 134 may be referred to as a pull-back process. In the pull-back process, an etch recipe may be used, in which while the plurality of first horizontal electrode portions 132 may have a relatively decreased etch speed, the plurality of first mold insulating layers 134 may have a relatively increased etch speed. In some implementations, in the pull-back process, an etchant including H₃PO₄ may be used.

The plurality of openings OP may be spaces defined between the plurality of first horizontal electrode portions 132 after the portions of the plurality of first mold insulating layers 134 are removed. In some implementations, the plurality of openings OP may have an annular-shaped horizontal section surrounding the second vertical hole 144H. The plurality of openings OP may have a relatively increased width in a lateral direction. The plurality of openings OP may form a concentric circle with respect to the second vertical hole 144H. For example, lateral distances Ld in a radial direction from a side wall of each of the plurality of openings OP to the second vertical hole 144H may be identical.

In some implementations, as illustrated in FIG. 19B, the second vertical hole 144H may have a circular horizontal section, and each of the plurality of openings OP may have an annular horizontal section forming a concentric circle with the second vertical hole 144H. In some implementations, as illustrated in FIG. 7, the second vertical hole 144H may have a bar-shaped horizontal section extending in the first horizontal direction HD1, and here, the plurality of openings OP may include a first opening OP1 arranged at a first side of the second vertical hole 144H and a second opening OP2 arranged at a second side of the second vertical hole 144H.

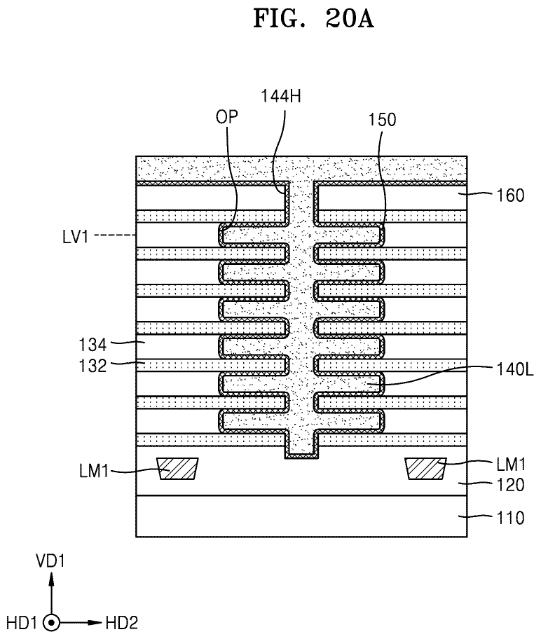

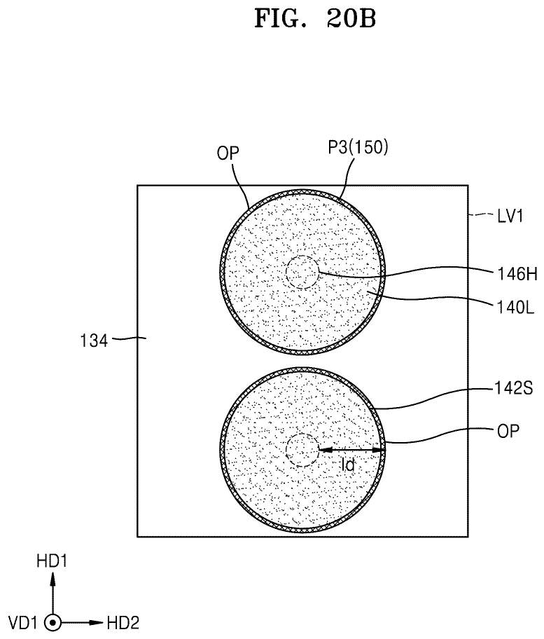

Referring to FIGS. 20A and 20B, the capacitor dielectric layer 150 may be conformally formed in the second vertical hole 144H and the plurality of openings OP, and a second electrode layer 140L filling the second vertical hole 144H and the plurality of openings OP may be formed on the capacitor dielectric layer 150.

A portion of the second electrode layer 140L may fill spaces between the plurality of first horizontal electrode portions 132, and the capacitor dielectric layer 150 may be arranged between the second electrode layer 140L and the plurality of first horizontal electrode portions 132.

In some implementations, the second electrode layer 140L may include at least one of TiN, TaN, WN, MON, NON, CON, Ti, Ta, W, Ru, Mo, Nb, Co, and a silicide thereof.

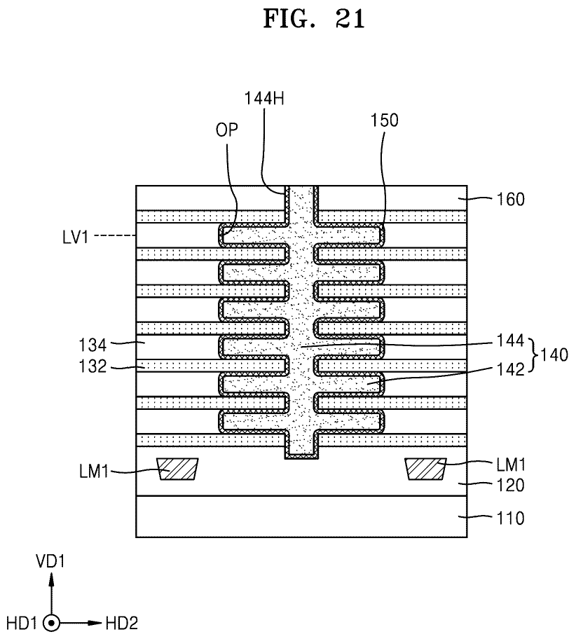

Referring to FIG. 21, the capacitor dielectric layer 150 and the second electrode layer 140L arranged on an upper surface of the upper insulating layer 160 may be removed. Here, portions of the second electrode layer 140L, the portions filling the plurality of openings OP, may be referred to as the second horizontal electrode portions 142, and a portion of the second electrode layer 140L, the portion filling the second vertical hole 144H and extending in the vertical direction VD1, may be referred to as the second conductive pillar 144.

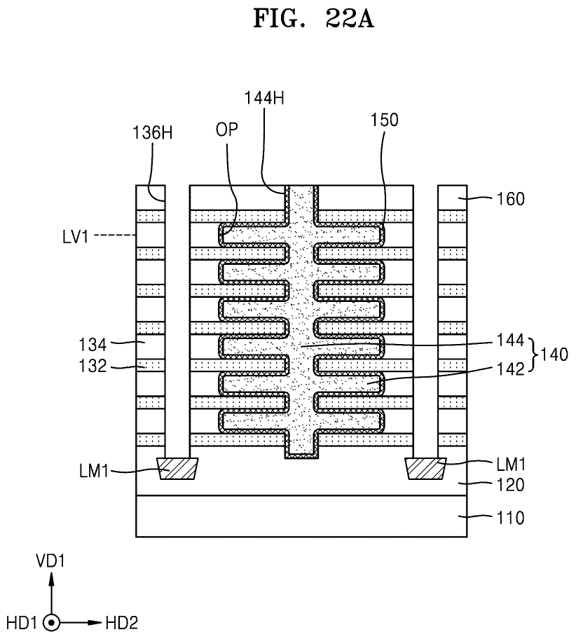

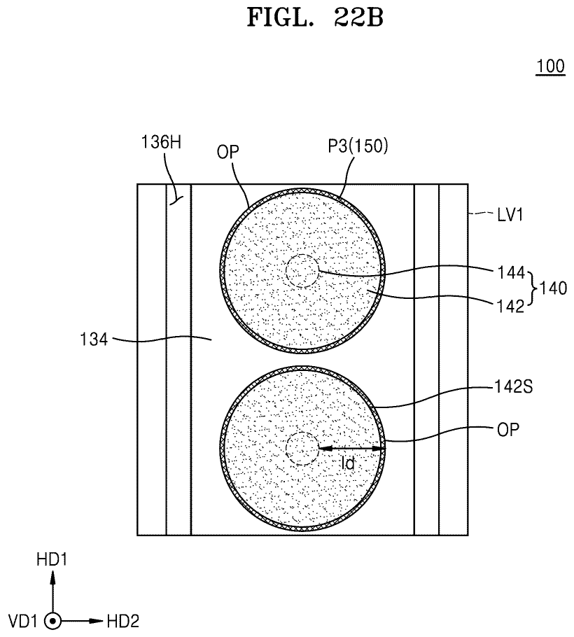

Referring to FIGS. 22A and 22B, a mask pattern may be formed on the upper insulating layer 160, and the mask pattern may be used as an etch mask to remove portions of the plurality of first horizontal electrode portions 132 and the plurality of first mold insulating layer 134 to form the first vertical hole 136H. The first vertical hole 136H may be arranged at a lower level than the lowermost first horizontal electrode portion 132, and an upper surface of the first lower conductive line LM1 may be exposed to a bottom portion of the first vertical hole 136H.

In some implementations, as illustrated in FIG. 22B, the first vertical hole 136H may have a bar-shaped horizontal section extending in the first horizontal direction HD1. In some implementations, as illustrated in FIG. 5, the first vertical hole 136H may have a circular horizontal section.

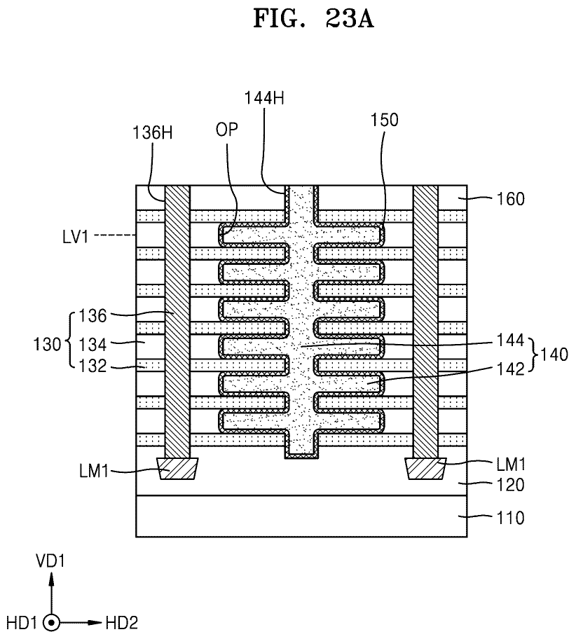

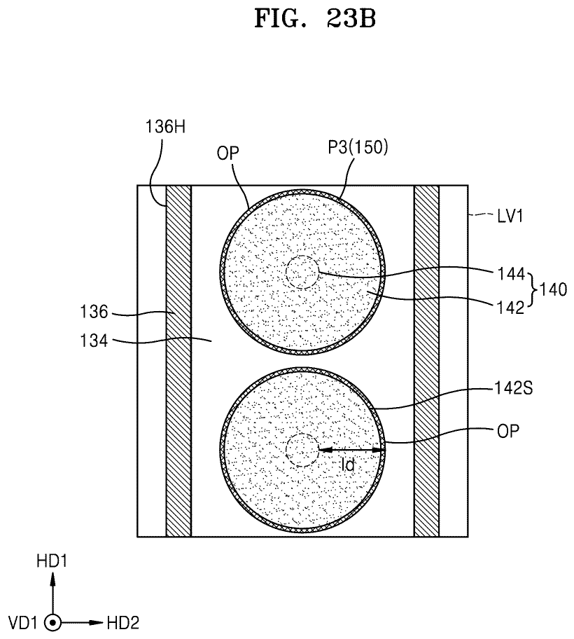

Referring to FIGS. 23A and 23B, the first conductive pillar 136 may be formed in the first vertical hole 136H. The first conductive pillar 136 may include at least one of TiN, TaN, WN, MON, NbN, CON, Ti, Ta, W, Ru, Mo, Nb, Co, and a silicide thereof.

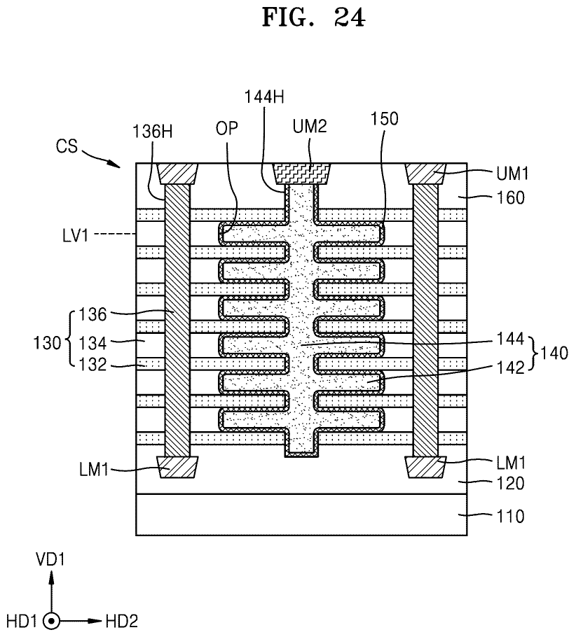

Referring to FIG. 24, a line trench may be formed by removing a portion of the upper insulating layer 160, and the first upper conductive line UM1 and the second upper conductive line UM2 may be formed in the line trench. The first upper conductive line UM1 may be electrically connected to the first conductive pillar 136, and the second upper conductive line UM2 may be electrically connected to the second conductive pillar 144.

By using the process described above, the semiconductor device 100 may be formed.

In some implementations, through a pull-back process, portions of the plurality of first mold insulating layers 134 may be removed and the plurality of openings OP may be formed. Accordingly, the three-dimensional capacitor structure CS having a three-dimensional structure and having a relatively increased effective capacitor area may be obtained.

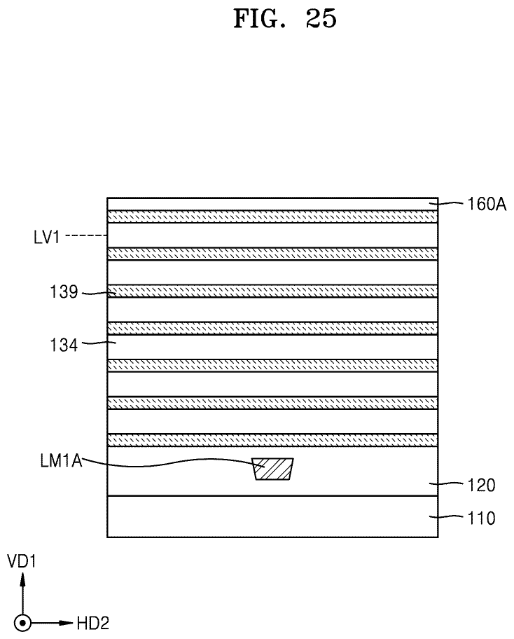

FIGS. 25 to 28 are schematic views showing another example of a method of manufacturing the semiconductor device 100D.

Referring to FIG. 25, the plurality of first mold insulating layers 134 and the plurality of second mold insulating layers 139 may be alternately formed on the lower structure 120.

In some implementations, the plurality of first mold insulating layers 134 and the plurality of second mold insulating layers 139 may include materials having etch selectivities with respect to each other. For example, the plurality of first mold insulating layers 134 and the plurality of second mold insulating layers 139 may include at least one of silicon oxide, silicon nitride, silicon oxynitride, silicon carbide, and silicon carbon oxide. For example, the plurality of first mold insulating layers 134 may include silicon nitride, and the plurality of second mold insulating layers 139 may include silicon oxide.

Thereafter, the first upper insulating layer 160A may be formed on the uppermost second mold insulating layer 139.

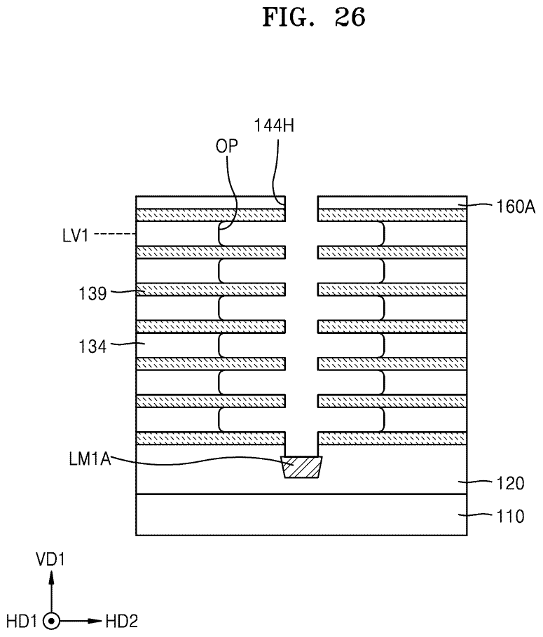

Referring to FIG. 26, portions of the plurality of first mold insulating layers 134 and the plurality of second mold insulating layers 139 may be removed to form the second vertical hole 144H.

Thereafter, portions of the plurality of first mold insulating layers 134, exposed through a side wall of the second vertical hole 144H, may be removed, and the plurality of openings OP may be formed. In some implementations, in a process for removing the portions of the plurality of first mold insulating layers 134, the plurality of second mold insulating layers 139 may rarely be removed and may remain.

In some implementations, the process for removing the portions of the plurality of first mold insulating layers 134 may be referred to as a pull-back process. In the pull-back process, an etch recipe may be used, in which while the plurality of second mold insulating layers 139 may have a relatively decreased etch speed, the plurality of first mold insulating layers 134 may have a relatively increased etch speed. In some implementations, in the pull-back process, an etchant including H₃PO₄ may be used.

The second lower conductive line LM1A may be exposed to a bottom portion of the second vertical hole 144H. For example, in the pull-back process, an upper surface of the second lower conductive line LM1A may be exposed. Alternatively, in the pull-back process, the upper surface of the second lower conductive line LM1A may be covered by the lower structure 120 and may not be exposed to the bottom portion of the second vertical hole 144H, and the upper surface of the second lower conductive line LM1A may be exposed by using an additional etch process after the pull-back process.

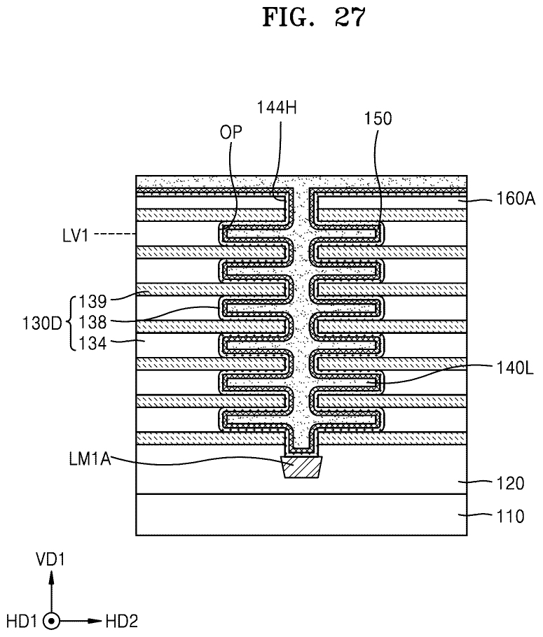

Referring to FIG. 27, the conductive electrode layer 138 and the capacitor dielectric layer 150 may be sequentially formed in the second vertical hole 144H and the plurality of openings OP, and the second electrode layer 140L filling the second vertical hole 144H and the plurality of openings OP may be formed on the capacitor dielectric layer 150.

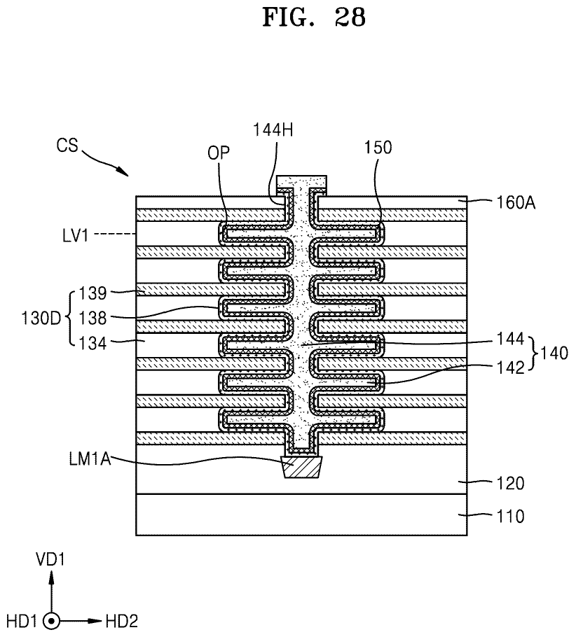

Referring to FIG. 28, the conductive electrode layer 138, the capacitor dielectric layer 150, and the second electrode layer 140L arranged on an upper surface of the first upper insulating layer 160A may be removed. Here, portions of the second electrode layer 140L, the portions being arranged in the plurality of openings OP, may be referred to as the second horizontal electrode portions 142, and a portion of the second electrode layer 140L, the portion filling the second vertical hole 144H and extending in the vertical direction VD1, may be referred to as the second conductive pillar 144.

Thereafter, referring to FIG. 13 again, the second upper insulating layer 160B covering the second conductive pillar 144 may be formed on the first upper insulating layer 160A. Thereafter, a line trench may be formed by removing a portion of the second upper insulating layer 160B, and the second upper conductive line UM2 may be formed in the line trench.

The semiconductor device 100D may be formed by the process described above.

In some implementations, through the pull-back process, portions of the plurality of first mold insulating layers 134 may be removed, and the plurality of openings OP may be formed. Accordingly, the three-dimensional capacitor structure CS having a three-dimensional structure and having a relatively increased effective capacitor area may be obtained.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been particularly shown and described with reference to example implementations thereof, it will be understood that various changes in form and details may be made therein without departing from the spirit and scope of the following claims.

What is claimed is:

1. A semiconductor device comprising a capacitor structure, the capacitor structure positioned on a substrate and comprising:
a first electrode structure comprising a plurality of first horizontal electrode portions and a first conductive pillar, the plurality of first horizontal electrode portions spaced apart from each other in a first direction perpendicular to an upper surface of the substrate, and the first conductive pillar connected to each first horizontal electrode portion of the plurality of first horizontal electrode portions and extending in the first direction;
a second electrode structure comprising a plurality of second horizontal electrode portions and a second conductive pillar, the second conductive pillar extending through the plurality of first horizontal electrode portions in the first direction, and the plurality of second horizontal electrode portions spaced apart from each other in the first direction on a side wall of the second conductive pillar and alternately arranged with the plurality of first horizontal electrode portions; and
a capacitor dielectric layer between the side wall of the second conductive pillar and the plurality of first horizontal electrode portions, and the capacitor dielectric layer on an upper surface, a side surface, and a bottom surface of each second horizontal electrode portion of the plurality of second horizontal electrode portions.

2. The semiconductor device of claim 1, wherein the second conductive pillar has a circular planar shape, and
wherein each second horizontal electrode portion of the plurality of second horizontal electrode portions has an annular planar shape surrounding the second conductive pillar.

3. The semiconductor device of claim 2, wherein a side surface of at least one second horizontal electrode portion of the plurality of second horizontal electrode portions forms a concentric circle with a side surface of a portion of the second conductive pillar, the portion of the second conductive pillar being at a same level as the at least one second horizontal electrode portion.

4. The semiconductor device of claim 1, wherein the first conductive pillar extends in a first horizontal direction, and
wherein the second conductive pillar extends in the first horizontal direction and is spaced apart from the first conductive pillar in a second horizontal direction.

5. The semiconductor device of claim 4, wherein each second horizontal electrode portion of the plurality of second horizontal electrode portions comprises a first sub-electrode portion on a first side surface of the second conductive pillar and a second sub-electrode portion on a second side surface of the second conductive pillar, the second side surface opposite to the first side surface, and
wherein in the second horizontal direction, a width of the first sub-electrode portion is same as a width of the second sub-electrode portion.

6. The semiconductor device of claim 1, wherein the first electrode structure comprises a plurality of mold insulating layers alternately arranged with the plurality of first horizontal electrode portions,
wherein the plurality of mold insulating layers respectively comprise a plurality of openings, and the plurality of mold insulating layers overlap each other in the first direction, and
wherein the plurality of second horizontal electrode portions are arranged in the plurality of openings.

7. The semiconductor device of claim 6, wherein a portion of the capacitor dielectric layer is in a respective opening of the plurality of openings of the plurality of mold insulating layers.

8. The semiconductor device of claim 6, wherein a portion of the capacitor dielectric layer is in contact with a respective mold insulating layer of the plurality of mold insulating layers.

9. The semiconductor device of claim 6, wherein the plurality of mold insulating layers comprise silicon nitride, and
wherein the plurality of first horizontal electrode portions comprise doped or non-doped polysilicon.

10. The semiconductor device of claim 1, wherein the first electrode structure comprises a conductive electrode layer between the plurality of first horizontal electrode portions and the capacitor dielectric layer and between a plurality of mold insulating layers and the capacitor dielectric layer, and
wherein the conductive electrode layer comprises at least one of titanium, tantalum, tungsten, molybdenum, niobium, titanium nitride, tantalum nitride, tungsten nitride, molybdenum nitride, or niobium nitride.

11. The semiconductor device of claim 1, wherein each first horizontal electrode portion of the plurality of first horizontal electrode portions comprises a first concavo-convex surface, and
wherein each second horizontal electrode portion of the plurality of second horizontal electrode portions comprises a second concavo-convex surface conforming to a shape of the first concavo-convex surface.

12. A semiconductor device comprising a capacitor structure, the capacitor structure positioned on a substrate and comprising:
a first electrode structure comprising a plurality of first horizontal electrode portions, a plurality of mold insulating layers, and a first conductive pillar, the plurality of first horizontal electrode portions spaced apart from each other in a first direction perpendicular to an upper surface of the substrate, the plurality of mold insulating layers alternately arranged with the plurality of first horizontal electrode portions and respectively comprising a plurality of openings, the plurality of mold insulating layers overlapping each other in the first direction, and the first conductive pillar connected to each first horizontal electrode portion of the plurality of first horizontal electrode portions and extending in the first direction;
a second electrode structure comprising a plurality of second horizontal electrode portions and a second conductive pillar, the second conductive pillar extending through the plurality of first horizontal electrode portions in the first direction, and the plurality of second horizontal electrode portions spaced apart from each other in the first direction on a side wall of the second conductive pillar and arranged in the plurality of openings, respectively; and
a capacitor dielectric layer between the first electrode structure and the second electrode structure, the capacitor dielectric layer comprising a plurality of portions on an upper surface, a side surface, and a bottom surface of each second horizontal electrode portion of the plurality of second horizontal electrode portions, in the plurality of openings, respectively.

13. The semiconductor device of claim 12, wherein the plurality of second horizontal electrode portions are alternately arranged with the plurality of first horizontal electrode portions.

14. The semiconductor device of claim 12, wherein the second conductive pillar has a circular planar shape, and
wherein each opening of the plurality of openings has an annular planar shape surrounding the second conductive pillar.

15. The semiconductor device of claim 14, wherein a side surface of each second horizontal electrode portion of the plurality of second horizontal electrode portions forms a concentric circle with the side wall of the second conductive pillar.

16. The semiconductor device of claim 12, wherein the first conductive pillar extends in a first horizontal direction, and
wherein the second conductive pillar extends in the first horizontal direction and is spaced apart from the first conductive pillar in a second horizontal direction.

17. The semiconductor device of claim 16, wherein each second horizontal electrode portion of the plurality of second horizontal electrode portions comprises a first sub-electrode portion on a first side surface of the second conductive pillar and a second sub-electrode portion on a second side surface of the second conductive pillar, the second side surface opposite to the first side surface, and
wherein in the second horizontal direction, a width of the first sub-electrode portion is same as a width of the second sub-electrode portion.

18. The semiconductor device of claim 12, wherein the first electrode structure comprises a conductive electrode layer between the plurality of first horizontal electrode portions and the capacitor dielectric layer and between the plurality of mold insulating layers and the capacitor dielectric layer, and
wherein the conductive electrode layer comprises at least one of titanium, tantalum, tungsten, molybdenum, niobium, titanium nitride, tantalum nitride, tungsten nitride, molybdenum nitride, or niobium nitride.

19. A semiconductor device comprising:
a semiconductor substrate on which a plurality of pixel areas are defined, each pixel area comprising a photovoltaic area; and
a capacitor structure positioned on the semiconductor substrate and comprising:
a first electrode structure comprising a plurality of first horizontal electrode portions and a first conductive pillar, the plurality of first horizontal electrode portions spaced apart from each other in a first direction perpendicular to an upper surface of the semiconductor substrate, and the first conductive pillar connected to each first horizontal electrode portion of the plurality of first horizontal electrode portions and extending in the first direction;
a second electrode structure comprising a plurality of second horizontal electrode portions and a second conductive pillar, the second conductive pillar extending through the plurality of first horizontal electrode portions in the first direction, and the plurality of second horizontal electrode portions spaced apart from each other in the first direction on a side wall of the second conductive pillar and alternately arranged with the plurality of first horizontal electrode portions; and
a capacitor dielectric layer between the side wall of the second conductive pillar and the plurality of first horizontal electrode portions, and the capacitor dielectric layer on an upper surface, a side surface, and a bottom surface of each second horizontal electrode portion of the plurality of second horizontal electrode portions.

20. The semiconductor device of claim 19, wherein the first electrode structure comprises a plurality of mold insulating layers alternately arranged with the plurality of first horizontal electrode portions,
wherein the plurality of mold insulating layers respectively comprise a plurality of openings, and the plurality of mold insulating layers overlap each other in the first direction, and
wherein the plurality of second horizontal electrode portions are arranged in the plurality of openings.
